(19) United States
(12) Patent Application Publication
(10) Pub. No.: US 2006/0170094 A1
(43) Pub. Date: Aug. 3, 2006

(54) Semiconductor package integral heat spreader

(75) Inventors: Sankara J. Subramanian, Chandler, AZ (US); Abhay A. Watwe, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/050,330

(22) Filed: Feb. 2, 2005

(51) Int. Cl. H01L 23/34

(52) U.S. Cl. 257/706

(57) ABSTRACT

An integral heat spreader is disclosed wherein its physical characteristics are modified in regions between adjacent semiconductor devices. The modification improves the reliability of the semiconductor devices by reducing stiffness of the integral heat spreader.

### FIELD OF THE INVENTION

Embodiments of the present invention relate generally to semiconductor technology and more specifically to semiconductor packaging.

### BACKGROUND OF THE INVENTION

Current microprocessor trends—higher frequencies, smaller die size, and increased power—are all contributing to increased heat being generated by semiconductor devices. Too much heat can corrupt the microprocessor's data and/or cause the microprocessor (or other components) to fail. Conventional methods for addressing heating effects include using passive thermal management structures (i.e., heat sinks, integral heat spreaders (IHS), etc,) to dissipate heat produced during the device's operation. An IHS can be used alone or in conjunction with a heat sink. To the extent they are used together, the IHS enhances the heat sink's ability to dissipate heat by increasing the heat transfer area between the semiconductor device and the heat sink.

Shown in FIG. 7 is a cross-sectional view illustrating a semiconductor device package 700 that includes an integral heat spreader 712 and heat sink 714 used in conjunction with a semiconductor device 706. In FIG. 7, the semiconductor device 706 is flip-chip mounted in a ball grid array (BGA) package. In a flip-chip configuration, a semiconductor device 706 is mounted top-side down to a substrate 702 so that bond pads on the semiconductor device 706 electrically connect with traces on the substrate 702 by way of controlled collapse chip connection (C4) bumps 708. Underfill material 709 occupies regions between the semiconductor device 706 and the substrate 702, and fillets 710 (formed from underfill material) are formed along the sidewalls of the semiconductor device 706.

In BGA packages, as described here, traces on the semiconductor device side of the substrate 702 electrically connect with traces on the opposite side of the substrate 702 by way of plated-through-holes (PTH) and/or vias (not shown). The traces on the opposite side of the substrate 702 can be used to electrically connect with a printed circuit board (PCB) (not shown) by way of solder balls 704.

As shown in FIG. 7, an integral heat spreader 712 is cooperatively coupled to the semiconductor device 706. Here, the IHS 712 interfaces with the backside of the semiconductor device by way of a thermal-interface material (TIM) 711. The TIM 711 is typically a low thermal resistance material that attaches the IHS 712 with the semiconductor device 706. The purpose of the TIM 711 is to provide a pathway to conduct heat from the semiconductor device 706 into the IHS 712. By itself, the IHS can function as a heat sink. Alternatively, as shown here, a separate heat sink 714 can be used with the IHS to enhance thermal management capabilities. The heat sink can be mechanically coupled to the IHS and typically interfaces with it by way of a second TIM 713, such as, for example, thermal grease. The heat sink dissipates heat away from the semiconductor device 706 to the heat sink 714 via TIM 711, IHS 712, and TIM 713.

To the extent that the coefficients of thermal expansion (CTE) of the IHS 712, the semiconductor device 706, and the substrate 702 are different, temperature changes can produce stresses that affect the packaged device's performance. For example, stresses resulting from CTE mismatch can induce delamination of the TIM 711 and cause fatigue failures in the solder joints 704. Solder joint failures can impact the packaged semiconductor device's yield/reliability. Delamination of the TIM will impede its ability to transfer heat into the IHS and can result in the semiconductor device 712 operating at temperatures that exceeds specification limits. Ultimately, this can impact semiconductor device 706 speed and reliability.

### BRIEF DESCRIPTION OF THE DRAWINGS

FIG. 1 illustrates a cross-sectional view of a semiconductor device package that includes an integral heat spreader used in conjunction with multiple semiconductor devices.

FIG. 2 illustrates a top-down view of the package shown in FIG. 1.

FIG. 3 illustrates a cross-sectional view of a semiconductor device package that includes an integral heat spreader incorporating an embodiment of the present invention.

FIG. 4 illustrates a top-down view of the package shown in FIG. 3.

FIG. 5 illustrates a cross-sectional view of semiconductor device package that includes an integral heat spreader incorporating an alternative embodiment of the present invention.

FIG. 6 illustrates a cross-sectional view of semiconductor device package that includes an integral heat spreader incorporating an alternative embodiment of the present invention.

FIG. 7 illustrates a cross-sectional view of semiconductor device package containing a single semiconductor device that includes a conventional integral heat spreader and heat sink.

It will be appreciated that for simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, an integral heat spreader apparatus for a multi-chip package is disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

Microcomputers are currently being used in homes and business for a variety of applications such as word processing, spreadsheets, web browsing, graphics, games, etc. Such data processing systems typically use a single microprocessor, or central processing unit (CPU) embodied in a single semiconductor package. By contrast, microcomputers designed for more demanding tasks (e.g., network servers) commonly include multiple CPUs. While increasing the number of available processors augments computing power, it can also create heat-related reliability problems, especially when the heat is being generated by more than one state-of-the-art microprocessor or other semiconductor device.

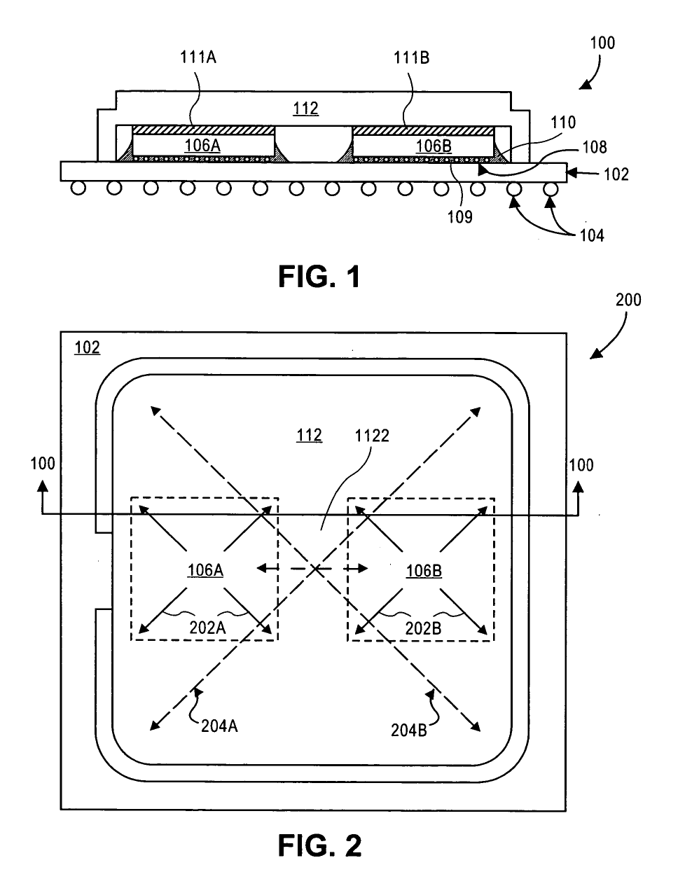

Shown in FIG. 1 is an illustration of a cross-sectional view of a portion of a multi-chip package 100 that includes an IHS 112 coupled by way of TIMs 111A and 111B to semiconductor devices (semiconductor die) 106A and 106B, respectively. In one embodiment, the TIMs 111A and 111B comprise a high indium-content material. The semiconductor devices 106A and 106B can be mounted to a substrate 102 via C4 bumps 108 and underfill material 109. Fillets 110 are formed along sidewalls of the semiconductor devices 106A and 106B. The multi-chip package 100 typically communicates with external circuitry by way of the solder balls 104.

As can be seen in FIG. 1, the current IHS design for a multi-chip package is fundamentally the same as it is for a prior art single-chip package. That is, the IHS is basically a single continuous thermally-conducting material (typically comprised of an oxygen-free copper material). However, to the extent that the TIMs 111A and 111B attach multiple chips (e.g., semiconductor devices 106A and 106B) to the IHS 112, CTE mismatch considerations can be compounded as compared to prior art single-chip (single-die) packages.

Shown in FIG. 2 is a top down view 200 of the semiconductor package 100 shown in FIG. 1. The present inventors have determined that dual-chip (dual-die) and multi-chip packages (i.e., packages that contain more than one semiconductor die), experience higher stress levels as compared to a single-chip package. The increased stresses are produced as a result of CTE mismatch interactions between semiconductor device 106A, semiconductor device 106B, the IHS 112, and the substrate 102.

Referring now to both FIGS. 1 and 2, in so far as the TIMs 111A and 111B rigidly attach the IHS 112 to multiple semiconductor devices (i.e. 106A and 106B), the expansion/contraction of one semiconductor device (e.g., 106A) can now also produce stresses that contribute to stress induced failures of the other semiconductor device (e.g. 106B) in the package. Arrows 204A/204B illustrate possible directions of expansion (or alternatively, contraction when the arrows point in the opposite direction) of the IHS 112, and arrows 202A and 202B illustrate possible directions of expansion (or alternatively, contraction when the arrows point in the opposite direction) of semiconductor devices 106A and 106B, respectively.

To the extent that the magnitude and/or direction of forces produced by the expansion/contraction of the IHS 112 and the semiconductor devices 106A and 106B are inconsistent with each other, then shear and peel stresses can be generated at the interfaces between the IHS 112 and the TIMs 111A and 111B and throughout the bulk of the TIMs. These stresses can produce problems related to TIM delamination and cracking, C4 bump 108 joint reliability failures, underfill 109 delamination, fillet 110 cracking, and delamination/cracking of various interlevel dielectric (ILD) layers in the semiconductor devices. The present inventors have determined that the stiffness of the IHS, (i.e., its inability to accommodate the expansion/contraction of semiconductor devices 106A and 106B) in particular in and around region 1122 (regions between the semiconductor devices) can aggravate these problems.

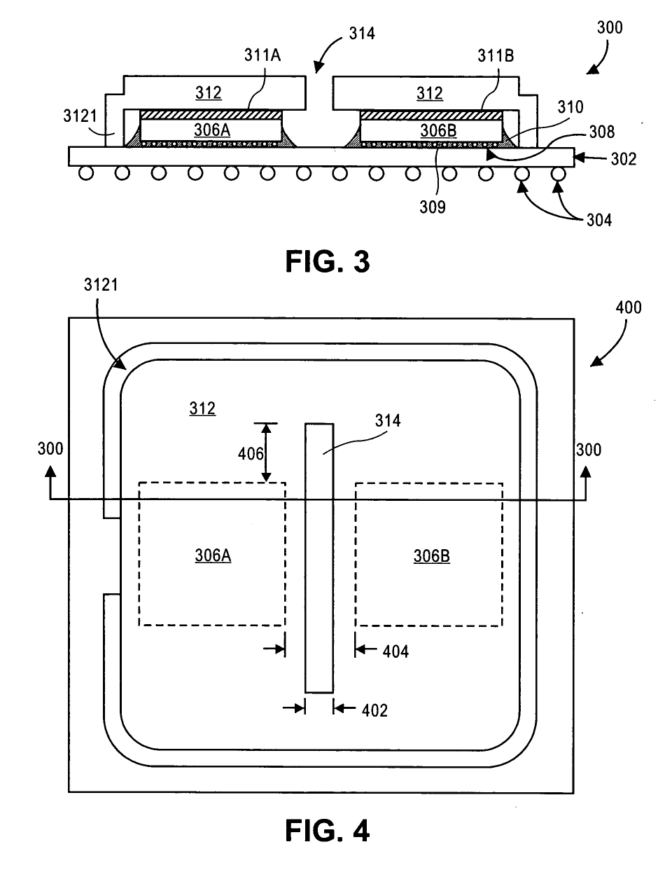

In FIG. 3, a cross-sectional view of a semiconductor package 300 is illustrated which includes a modified IHS in accordance with one embodiment of the present invention. Elements 302, 304, 306A, 306B, 308, 309, 310, and 311A/311B are all functionally equivalent (or nearly functionally equivalent) to FIG. 1 elements 102, 104, 106A, 106B, 108, 109, 110, and 111A/111B, respectively, so unnecessary repetitive discussion of these elements will be omitted. The IHS 312 however has been modified to include a stress relief slot 314 that among other things can function as an IHS stiffness-reduction feature. In one implementation of this embodiment, the stress relief slot 314 is a physical discontinuity, such as an opening that extends through the entire thickness of the IHS 312 as shown in FIG. 3. In this embodiment, the IHS 312 includes edge regions 3121 that are shown as contacting the substrate 302. However, it should be pointed out that this is not necessarily a requirement for this or other embodiments of the present invention.

Turning now to FIG. 4, a top-down view 400 of the semiconductor package 300 is illustrated. As shown in FIG. 4, the slot 314 can be an opening that extends completely across regions of the IHS between the semiconductor devices 306A and 306B. In one embodiment, the width of the opening 402 is narrower than the distance 404 separating the semiconductor devices 306A and 306B. The stress relief slot 314 can reduce stresses by decreasing the stiffness of the IHS in the region between the two semiconductor devices 306A and 306B. This in turn reduces interactive push-and-pull effects on TIMs 311A and 311B due to CTE and other mismatches between IHS 312, semiconductor devices 306A and 306B, and substrate 302.

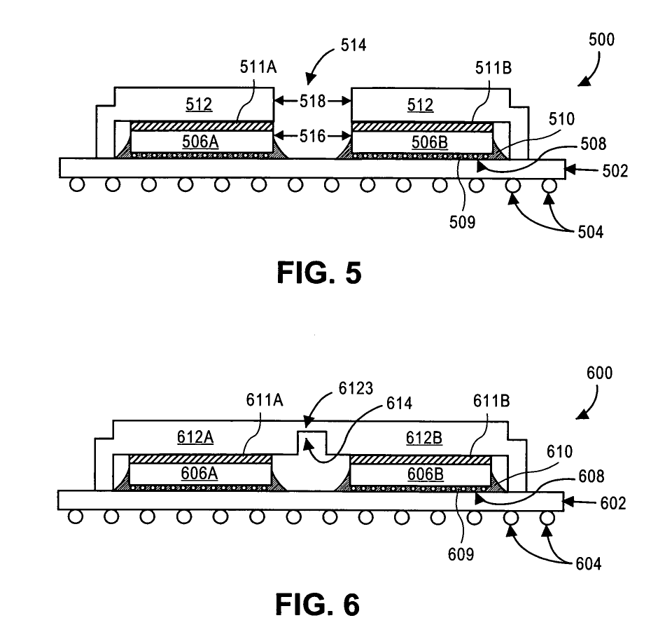

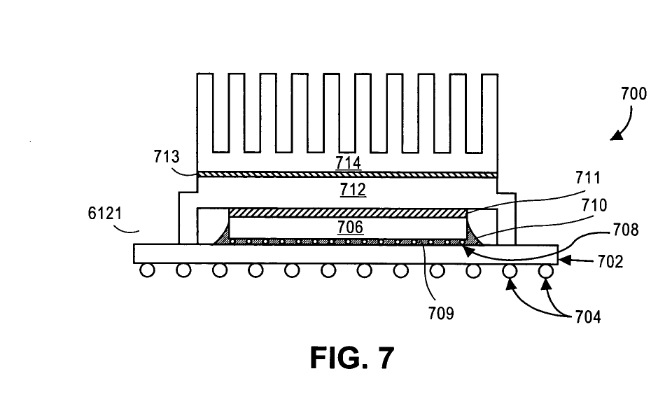

Turning now to FIGS. 5 and 6, alternative embodiments are shown in semiconductor package cross-sectional views 500 and 600. Elements 502, 504, 506A, 506B, 508, 509, 510, and 511A/511B of FIG. 5 and elements 602, 604, 606A, 606B, 608, 609, 610, and 611A/611B of FIG. 6 are all functionally equivalent (or nearly functionally equivalent) to FIG. 1 elements 102, 104, 106A, 106B, 108, 109, 110, and 111A/111B, respectively, so unnecessary repetitive discussion of these elements will be omitted. In the embodiment shown in FIG. 5, the slot 514 is wider than the slot 314 shown in FIG. 3. Here, the slot's width dimension 518 is approximately the same as the dimension (i.e. distance 516) separating semiconductor devices 506A and 506B. One of ordinary skill appreciates that a number of alternative embodiments exist with respect to the slot's width. For example, the slot width can be a dimension somewhere in between the dimensions 314 (FIG. 3) and 514 (FIG. 5). Or, the slot width can exceed the distance separating the semiconductor devices (e.g., the width of dimension 518 can exceed the width of dimension 516).

In addition, while the slot's shape (as shown in FIG. 4) is illustrated as single continuous opening 314 that extends completely across regions of the IHS 312 between the semiconductor devices 306A and 306B, alternative embodiments exist that include using continuous opening(s) that only extend partially across regions of the IHS 312 between the semiconductor devices. In addition, instead of being a single continuous opening, the slot 314 can alternatively comprise a plurality of discrete serial, parallel, or randomly positioned openings that extend either completely or partially across regions of the IHS 312 between semiconductor devices 306A and 306B. One of ordinary skill appreciates that a number of alternative embodiments exist with respect to the shapes and sizes of the opening(s) between the semiconductor devices.

Shown in FIG. 6 is an alternative embodiment wherein instead of removing the entire thickness of the IHS only a portion of the IHS thickness is removed. In this embodiment, the physical discontinuity includes a trench 614 (instead of an opening) formed in the IHS. Here, a ligament of material 6123 remains that connects the IHS regions 612A and 612B (IHS regions above the two semiconductor devices 606A and 606B). The ligament 6123 can be a single continuous remaining portion of the IHS that extends the length of the trench or it can include discontinuities (e.g. openings or the like), whereby straps of remaining ligament material connect IHS regions 612A and 612B.

From a mechanical standpoint (i.e. stiffness reduction and/or the ability to accommodate expansion and contraction of the semiconductor devices), embodiments disclosed in FIGS. 3 and 5 approximate each other. In other words, the stiffness reduction does not appear to depend on the width of the cut. On the other hand, stiffness reduction can be improved in certain implementations by extending the length of the opening beyond the width of the semiconductor device. For example, as shown in FIG. 4, the length of the opening 314 extends a distance 406 beyond the edge of the semiconductor device 306A. In this implementation, stiffness reduction may be improved over an opening having a length that does not extend beyond the width of the semiconductor device.

With respect to the IHS's heat conductivity effectiveness (i.e. its ability to remove heat generated by the semiconductor device), the present inventors have determined that both the trenched and the notched IHS designs result in virtually the same steady state die temperature as the conventional IHS design (FIG. 1). Consequently, there may be little to no adverse impact on the package's thermal performance due to use of one or more embodiments of present invention. More specifically, using thermal simulations, the relative thermal performance of the conventional continuous IHS (FIG. 1), the slotted IHS (FIG. 5) and the trenched IHS (FIG. 6) were compared. The trenched IHS of FIG. 6 (wherein the ligament was continuous and had a thickness that was approximately one-fourth of the thickness of the IHS) was found to produce an increase in die temperature of only approximately 0.1 degree Celsius as compared to the IHS shown in FIG. 1. And, the slotted IHS of FIG. 5 was found to produce an increase in die temperature of only approximately 0.3 degrees Celsius as compared to the IHS shown in FIG. 1. Considering that die temperatures can be on the order of 100 degrees Celsius during normal operation, relatively little change in thermal performance occurred as a result of incorporating these particular embodiments as compared to the thermal performance of the conventional IHS of FIG. 1.

With respect to the modified integral heat spreader's ability to improved reliability (i.e. to reduce stress and stress-induced failures), the present inventors have determined, through mechanical modeling using the finite-element method, that the compliant IHS designs disclosed in FIGS. 3 and 5 can improve reliability as compared to the conventional multi-chip IHS of FIG. 1. More specifically, in specific implementations of the embodiments of FIGS. 3 and 5, both designs resulted in substantially similar mechanical results. That is, using the IHS designs of FIGS. 3 and 5 (as compared to the IHS design of FIG. 1), die stresses, underfill-to-die interfacial stress, underfill-to-substrate interfacial stress, and TIM-to-die interfacial stress were reduced by approximately 20%, 23%, 30%, and 17%, respectively. It is believed that the mechanical performance of the trenched IHS (FIG. 6) is somewhere between that of the IHS of FIG. 1 and the IHS of FIGS. 3 and 5.

These results indicate that embodiments of the present invention can substantially improve reliability of multi-chip packages with minimal impact to thermal performance. The reduction in TIM-to-die interfacial stress may be significant because the risk of encountering TIM delamination failures can be higher in multi-chip packages (as compared to single-chip packages). Moreover, to the extent that semiconductor manufacturers use tin-silver solder bumps (for the bumps, 608, 508, 308, and 108 in FIGS. 6, 5, 3, and 1, respectively), which are softer and more pliant/malleable, problems with TIM-to-die interfacial delamination are currently believed to be mitigated. As the semiconductor industry moves to using stiffer, less pliant bump materials, such as copper, it is believed that issues with respect to TIM-to-die interfacial stress will become even more problematic. This may make the use of embodiments of the present invention all the more advantageous.

Embodiments of the present invention can advantageously reduce the effects of IHS stiffness. Implementations of these embodiments can be used to manufacture and use multi-chip packages that incorporate integral heat spreader technology. Embodiments of the present invention are not necessarily limited to the formation of slots and/or trenches in an IHS. On the other hand, embodiments of the present invention are intended to encompass any modification to the IHS in regions near or between adjacent semiconductor devices that reduces the stiffness of the IHS. Therefore, for example, the IHS could comprise two or more adjoining materials, wherein the material between the semiconductor devices is selected to reduce stiffness. Or, the IHS could include etched, stamped, raised, thickened, multi-layered materials, or combinations of these (and/or the foregoing features described in FIGS. 3-6) between or near the semiconductor devices to reduce stiffness.

The various implementations described above have been presented by way of example and not by way of limitation. Thus, for example, while embodiments disclosed herein reference flip-chip mounted semiconductor devices in BGA packages. One of ordinary skill appreciates that semiconductor devices which have been mounted to a substrate using other techniques or using other package types (e.g., pin grid array (PGA) packages, land grid array (LGA) packages, or any package-type that uses an IHS) can advantageously use integral heat spreaders incorporating one or more embodiments of the present invention to improve package reliability. A further advantage of one of more embodiments of the present invention includes that these integral heat spreaders may be easy to manufacture and do not require significant reinvestments in retooling.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An apparatus comprising:
a first semiconductor device and a second semiconductor device overlying a package substrate;
an integral heat spreader overlying the first semiconductor device and the second semiconductor device, wherein a physical property of the integral heat spreader is discontinuous in regions between the first semiconductor device and the second semiconductor device.

2. The apparatus of claim 1 wherein regions of the integral heat spreader between first semiconductor device and the second semiconductor device include a trench.

3. The apparatus of claim 2, wherein a ligament associated with the trench is discontinuous along the length of the trench.

4. The apparatus of claim 2, wherein the trench is further characterized as comprising a series of discrete trench segments that extend across regions of the integral heat spreader between the first semiconductor device and the second semiconductor device.

5. The apparatus of claim 2, wherein the trench extends completely across regions of the integral heat spreader between the first semiconductor device and the second semiconductor device.

6. The apparatus of claim 2, wherein the trench extends partially across regions of the integral heat spreader between the first semiconductor device and the second semiconductor device.

7. The apparatus of claim 1, wherein regions between first semiconductor device and the second semiconductor device include an opening in the integral heat spreader.

8. The apparatus of claim 7, wherein the opening extends completely across regions of the integral heat spreader between the first semiconductor device and the second semiconductor device.

9. The apparatus of claim 7, wherein the opening is further characterized as a plurality of discrete serial openings that extend completely across regions of the integral heat spreader between the first semiconductor device and the second semiconductor device.

10. The apparatus of claim 7, wherein the opening partially extends across regions of the integral heat spreader between the first semiconductor device and the second semiconductor device.

11. A semiconductor package comprising:
At least a first and second semiconductor die; and
an integral heat spreader cooperatively coupled to the first and second semiconductor die, wherein the integral heat spreader includes a stiffness-reduction feature.

12. The semiconductor package of claim 11, wherein the stiffness-reduction feature is located between the first and second semiconductor die.

13. The semiconductor package of claim 11, wherein the stiffness-reduction feature is further characterized as an opening in the integral heat spreader between the first and second semiconductor die.

14. The semiconductor package of claim 13, wherein the opening extends completely across regions of the integral heat spreader between the first and second die.

15. The semiconductor package of claim 14, wherein the opening extends through an entire thickness of the integral heat spreader

16. The semiconductor package of claim 15, wherein the opening has a width dimension that approximates a dimension separating the first and second die.

17. The semiconductor package of claim 15, wherein the opening has a width dimension that is less than a dimension separating the first and second die.

18. The semiconductor package of claim 15, wherein the opening has a width dimension that is greater than a dimension separating the first and second die.

19. The semiconductor package of claim 13, wherein the opening extends partially across regions of the integral heat spreader between the first and second die.

20. The semiconductor package of claim 12, wherein the stiffness-reduction feature is further characterized as one of a plurality of discrete serial openings in the integral heat spreader between the first and second die and a plurality of discrete parallel openings in the integral heat spreader between the first and second die.

21. The semiconductor package of claim 20, wherein a length of the stiffness-reduction feature extends one of partially across regions of the integral heat spreader between the first and second die and completely across regions of the integral heat spreader between the first and second die.

22. The semiconductor package of claim 12, wherein the stiffness-reduction feature is further characterized as trench in portions of the integral heat spreader between the first and second die.

23. The semiconductor package of claim 22, wherein regions of the trench include discontinuities.

24. An integral heat spreader adapted to accommodate more than one semiconductor die, the integral heat spreader including a stress-reduction feature.

25. The integral heat spreader of claim 24, wherein the stress reduction feature is further characterized as one of a trench and an opening in the integral heat spreader.

26. The integral heat spreader of claim 25, wherein the stress reduction feature has a length that extends beyond a width of at least one of the more than one semiconductor die.

27. The integral heat spreader of claim 24, wherein the stress reduction feature is further characterized as one of an etched feature, a stamped feature, a raised feature, and a multi-layered feature between a first semiconductor die and a second semiconductor die.

28. The integral heat spreader of claim 24, wherein the integral heat spreader comprises multiple adjoining materials.

29. The integral heat spreader of claim 28, wherein the stress reduction feature comprises a material that reduces stiffness in regions of the integral heat spreader between semiconductor devices attached to the integral heat spreader.
